(19) United States
(12) Patent Application Publication
(10) Pub. No.: US 2012/0098043 A1
(43) Pub. Date: Apr. 26, 2012

(54) SEMICONDUCTOR DEVICE HAVING METAL GATE AND MANUFACTURING METHOD THEREOF

(76) Inventors: Ya-Hsueh Hsieh, Kaohsiung County (TW); Teng-Chun Tsai, Tainan City (TW); Chia-Hsi Chen, Kao-Hsiung City (TW); Cheng-Huei Chang, Tainan County (TW); Po-Cheng Huang, Chiayi City (TW); Hsin-Kuo Hsu, Kaohsiung County (TW)

(21) Appl. No.: 12/911,714

(22) Filed: Oct. 25, 2010

(51) Int. Cl. H01L 29/78; H01L 21/28

(52) U.S. Cl. 257/288; 438/587; 257/E21.19; 257/E29.255

(57) ABSTRACT

A method of manufacturing a semiconductor device having metal gate includes providing a substrate having a semiconductor device and a contact etch stop layer (CESL) and a dielectric layer covering the semiconductor device formed thereon, wherein the semiconductor device having at least a dummy gate, performing a dummy gate removal step to form at least an opening in the semiconductor device and to simultaneously remove a portion of the CESL such that a top surface of the CESL is lower than the semiconductor device and the dielectric layer and a plurality of recesses is obtained, and performing a recess elimination step to form a substantially even surface of the dielectric layer.

### BACKGROUND OF THE INVENTION

1. Field of the Invention

The invention relates to a semiconductor device having a metal gate and manufacturing method thereof, and more particularly, to a semiconductor device having metal gate and manufacturing method applied with a gate last process.

2. Description of the Prior Art

With a trend towards scaling town the complementary metal-oxide semiconductor (CMOS) device size, conventional methods, which are used to achieve optimization, such as reducing thickness of the gate dielectric layer, for example the thickness of silicon dioxide layer, have faced problems such as leakage current due to tunneling effect. In order to keep progression to next generation, high-K materials are used to replace the conventional silicon oxide to be the gate dielectric layer because it decreases physical limit thickness effectively, reduces leakage current, and obtains equivalent capacitor in an identical equivalent oxide thickness (EOT).

On the other hand, the conventional polysilicon gate also has faced problems such as inferior performance due to boron penetration and unavoidable depletion effect which increases equivalent thickness of the gate dielectric layer, reduces gate capacitance, and worsens a driving force of the devices. Thus double work function metals are developed to replace the conventional polysilicon gate to be the control electrode that competent to the high-K gate dielectric layer.

In a CMOS device, one of the dual work function metal gates is used in an NMOS device and the other one is alternatively used in a PMOS device. It is well-known that compatibility and process control for the dual metal gate are more complicated, meanwhile thickness and composition controls for materials used in the dual metal gate method are more precise. The conventional dual metal gate methods are categorized into gate first process and gate last process. In a conventional dual metal gate method applied with the gate first process, the anneal process for forming the source/drain ultra-shallow junction, and the silicide process are performed after forming the metal gate. After the anneal process having such strict heat budget, it is found that a flat band voltage (V_{fb}) does not increase or decrease linearly with decrease of EOT of the high-K gate dielectric layer. Instead, a roll-off issue is observed. Therefore, the gate last process is developed to improve the V_{fb} roll-off issue and avoid generating leakage current due to re-crystallization of the high-K gate dielectric layer happened in high-temperature processes, and to widen material choices for the high-K gate dielectric layer and the metal gate in the gate first process.

In the conventional gate last process, a dummy gate or a replacement gate is provided and followed by performing processes used to construct a normal MOS transistor. Then, the dummy/replacement gate is removed to form a gate trench. Consequently, the gate trench is filled with metals according to the different electrical requirement. It is found that the gate last process is able to avoid processes of high thermal budget and to provide wider material choices for the high-K gate dielectric layer and the metal gate. However, the gate last process still faces integrity requirements for the complicated processes and reliability requirement for the gate trench filling.

### SUMMARY OF THE INVENTION

According to a first aspect of the present invention, there is provided a method of manufacturing a semiconductor device having metal gate. The method includes providing a substrate having at least a semiconductor device and a contact etch stop layer (CESL) and a dielectric layer covering the semiconductor device formed thereon, the semiconductor device have at least a dummy gate; performing a dummy gate removal step to form at least an opening in the semiconductor device, and to simultaneously remove a portion of the CESL such that a top surface of the CESL is lower than the semiconductor device and the dielectric layer and a plurality of recesses being obtained; and performing a recess elimination step to form a substantially even surface of the dielectric layer.

According to a second aspect of the present invention, there is provided a method of manufacturing a semiconductor device having metal gate. The method includes providing a substrate having a first transistor, a second transistor, and a CESL and a dielectric layer covering the first transistor and the second transistor formed thereon; performing a first dummy gate removal step to form a first opening in the first transistor and simultaneously remove a portion of the CESL such that a top surface of the CESL is lower than the first transistor and the dielectric layer and a plurality of first recesses is obtained; performing a first etching process to remove a portion of the dielectric layer such that a top surface of the dielectric layer and a bottom of the first recesses are co-planar; forming a first metal layer in the first opening; performing a second dummy gate removal step to form a second opening in the second transistor; and forming a second metal layer in the second opening.

According to a third aspect of the present invention, there is provided a method of manufacturing a semiconductor device having metal gate. The method includes providing a substrate having a first transistor, a second transistor, and a CESL and a dielectric layer covering the first transistor and the second transistor formed thereon; performing a first dummy gate removal step to form a first opening in the first transistor and simultaneously remove a portion of the CESL; forming a first metal layer in the first opening; performing a second dummy gate removal step to form a second opening in the second transistor and simultaneously remove a portion of the CESL; forming a second metal layer in the second opening; forming a filling metal layer filling at least the second opening on the substrate; performing a metal-CMP step to remove a portion of the filling metal layer; and performing a non-selectively CMP step such that the CESL, the dielectric layer and the filling metal layer are co-planar.

According to a fourth aspect of the present invention, there is provided a semiconductor device having metal gate. The semiconductor device includes a substrate, a metal gate formed on the substrate, a spacer formed on a sidewall of the metal gate, a CESL and a dielectric layer covering the spacer, a top surface of the CESL being lower than the spacer and the dielectric layer and forming at least a recess, and at least a metal layer filling the recess.

According to the semiconductor device having metal gate and manufacturing method provided by present invention, the recesses formed in the CESL are eliminated by performing the recess elimination step such as the etching process performed before forming the metal layers or the two-stepped planarization process performed after forming the metal layer. Consequently, the recesses and the metal filled within are all removed and thus the electrical performance of the semiconductor device will not be adversely impacted.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are schematic drawings illustrating a method of manufacturing a semiconductor device having metal gate provided by a first preferred embodiment of the present invention;

FIGS. 5-7 are schematic drawings illustrating a method of manufacturing a semiconductor device having metal gate provided by a second preferred embodiment of the present invention;

FIGS. 8-12 are schematic drawings illustrating a method of manufacturing a semiconductor device having metal gate provided by a third preferred embodiment of the present invention;

FIG. 13 is a schematic drawing illustrating a modification to the third preferred embodiment;

FIGS. 14-17 are schematic drawings illustrating a method of manufacturing a semiconductor device having metal gate provided by a fourth preferred embodiment of the present invention; and

FIG. 18 is a schematic drawing illustrating a modification to the fourth preferred embodiment.

### DETAILED DESCRIPTION

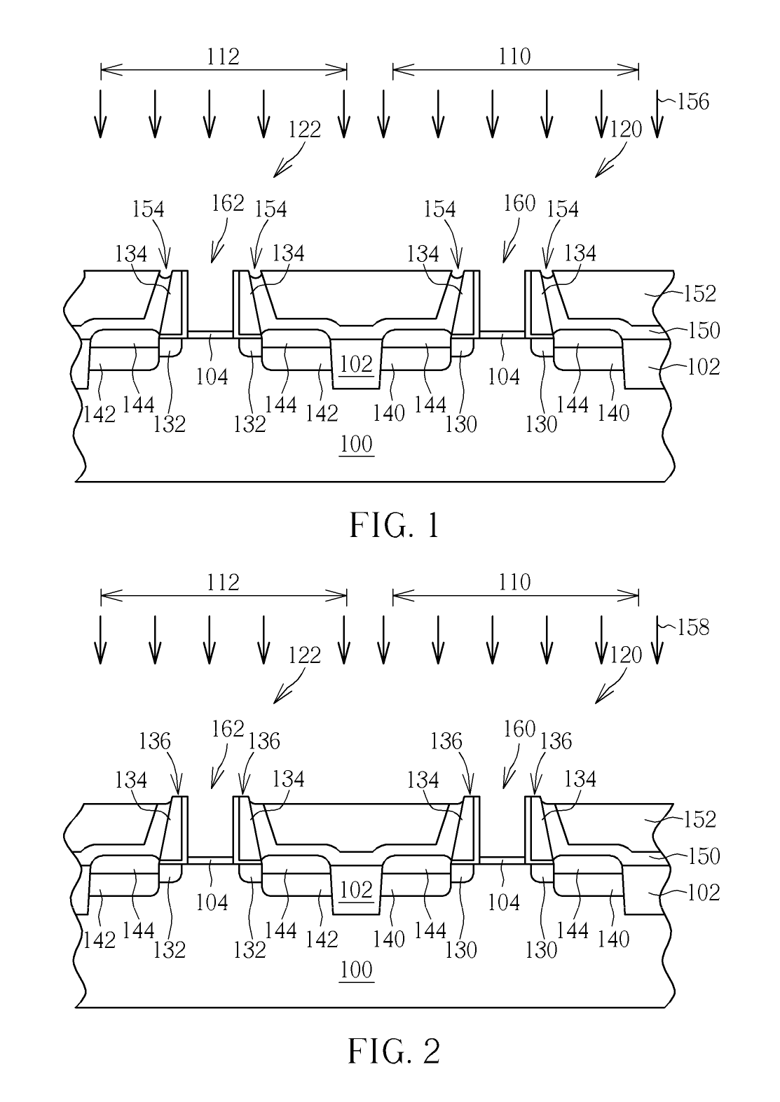

Please refer to FIGS. 1-4, which are schematic drawings illustrating a method of manufacturing a semiconductor device having metal gate provided by a first preferred embodiment of the present invention. As shown in FIG. 1, a substrate 100 such as silicon substrate, silicon-containing substrate, or silicon-on-insulator (SOI) substrate is provided. The substrate 100 includes a first active region 110 and a second active region 112 defined thereon. And a plurality of shallow trench isolation (STIs) 102 is formed in the substrate 100 for electrically isolating the first active region 110 and the second active region 112. Next, a first conductive-type transistor 120 and a second conductive-type transistor 122 are formed on the substrate 100 respectively in the first active region 110 and the second active region 112. In the preferred embodiment, the first conductive-type transistor 120 is a p-type transistor and the second conductive-type transistor 122 is an n-type transistor. However, those skilled in the art would easily realize that it is not limited to have the first conductive-type transistor 120 being an n-type transistor and the second conductive-type transistor 122 being a p-type transistor. Accordingly, the semiconductor device provided by the preferred embodiment is a CMOS device.

As shown in FIG. 1, the first conductive-type transistor 120 and the second conductive-type transistor 122 respectively include a gate dielectric layer 104, a dummy gate (not shown) such as a polysilicon layer, and a patterned hard mask (not shown). In the preferred embodiment, the gate dielectric layer 104 can be a conventional silicon oxide (SiO) layer or a high-K gate dielectric layer. The high-k gate dielectric layer is selected from the group consisting of silicon nitride (SiN), silicon oxynitride (SiON) and metal oxide. And the metal oxide comprises hafnium oxide (HfO), hafnium silicon oxide (HfSiO), hafnium silicon oxynitride (HfSiON), aluminum oxide (AIO), lanthanum oxide (LaO), lanthanum aluminum oxide (LaAIO), tantalum oxide (TaO), zirconium oxide (ZrO), zirconium silicon oxide (ZrSiO), or hafnium zirconium oxide (HfZrO).

Please refer to FIG. 1 again. The first conductive-type transistor 120 and the second conductive-type transistor 122 respectively include a first lightly-doped drain (LDD) 130 and a second LDD 132, a spacer 134, and a first source/drain 140 and a second source/drain 142. The spacer 134 can be a single-layered structure including silicon oxide (Si) or high temperature oxide (HTO) or a multi-layered structure comprising oxide-nitride-oxide (ONO) multilayer. Additionally, selective epitaxial growth (SEG) method can be utilized to form the first source/drain 140 and the second source/drain 142 in the preferred embodiment. For example, when the first conductive type transistor 120 is the p-type transistor and the second conductive type transistor 122 is the n-type transistor, epitaxial silicon layers with SiGe and SiC can be used to form the first source/drain 140 and the second source/drain 142, respectively. The SEG method is applied in the preferred embodiment for further improving drain induced barrier lowering (DIBL) and punchthrough effect and reducing off-state current leakage and power consumption. Thereafter, salicides 144 are formed on the first source/drain 140 and the second source/drain 142. After forming the first conductive-type transistor 120 and the second conductive-type transistor 122, a CESL 150 and an inter-layer dielectric (ILD) layer 152 are sequentially formed to cover the first conductive-type transistor 120 and the second conductive-type transistor 122 on the substrate 100.

Please still refer to FIG. 1. Then, a conventional planarization process such as a chemical mechanical polishing (CMP) process is performed to planarize the ILD layer 152 and the CESL 150 to expose the dummy gates. After the planarization process, a dummy gate removal step 156 is performed to remove the dummy gates of the first conductive-type transistor 120 and the second conductive-type transistor 122 simultaneously, and thus to form a first opening 160 and a second opening 162 respectively in the first conductive-type transistor 120 and the second conductive-type transistor 122. Additionally, the gate dielectric layer 104 is exposed in bottoms of the first opening 160 and the second opening 162. It is noteworthy the dummy gate removal step 156 simultaneously removes a portion of the CESL 150. Consequently, a top surface of the CESL 150 is lower than the spacers 134 of the first conductive-type transistor 120 and the second conductive-type transistor 122 and the ILD layer 152. Therefore, a plurality of recesses 154 is obtained. The recess 154 has a depth in a range of 50-150 angstroms (Å).

Please refer to FIG. 2. Next, a recess elimination step, preferably a dilute HF (DHF) etching process 158 such as a wet etching or dry etching process comprising the DHF is performed. The recess elimination step 158 is performed to remove a portion of the ILD layer 152. Consequently, a top surface of the ILD layer 152 and the CESL 150 and a bottom of the recesses 154 are coplanar. As shown in FIG. 2, it is observed the recesses 154 are eliminated and a substantially even surface of the ILD layer 152 from which a spacer protrusion 136 is formed and protruded is obtained after the recess elimination step 158.

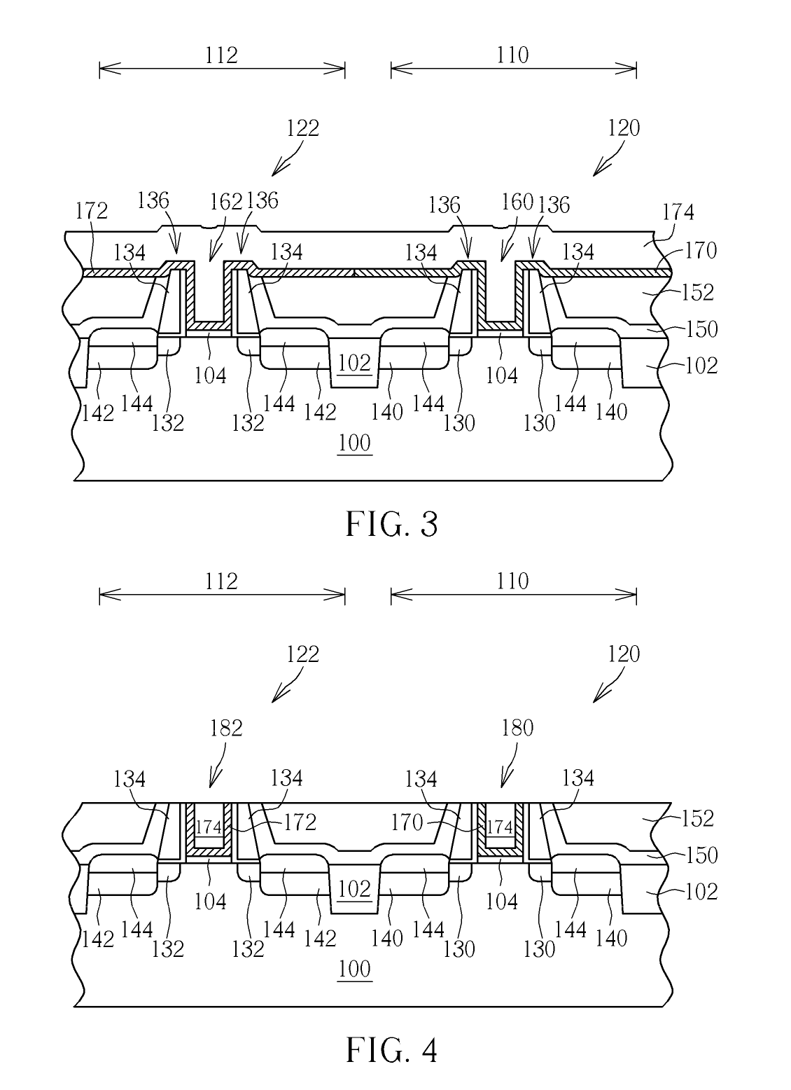

Please refer to FIG. 3. After the recess elimination step 158, a barrier layer (not shown) for preventing reaction or diffusion between the high-K gate dielectric layer 104 and the following formed metal layer is formed respectively in the first opening 160 and the second opening 162. Subsequently, a first metal layer 170 and a second metal layer 172 are respectively formed in the first opening 160 and the second opening 162. The first metal layer 170 includes a work function metal for p-type transistor such as material selected from the group consisting of titanium nitride (TiN) or tantalum carbide (TiC), and the second metal layer 172 includes a work function metal for n-type transistor such as material selected from the group consisting of TiAl, ZrAl, WAl, TaAl, or HfAl. After forming the first metal layer 170 and the second metal layer 172, a filling metal layer 174 is formed to fill the first opening 160 and the second opening 162 on the substrate 100. The filling metal layer 174 has superior gap-fill ability and is selected from the group consisting Al, W, Cu and preferably includes Al, but not limited to this.

It is noteworthy that the first metal layer 170 and the second metal layer 172 can be single-layered or multi-layered structure formed by different methods. For example, after forming the first metal layer 170 in the first opening 160 and the second opening 162, the first metal layer 170 in the second active region 112 is removed. Then, a second metal layer 172 is formed on the substrate 100 and followed by removing the second metal layer 172 in the first active region 110. In another variance, the second metal layer 172 is formed on the substrate 100 right after blanketly forming the first metal layer 170 in the first opening 160 and the second opening 162 and followed by removing the second metal layer 172 in the first active region 110. In other variance, an anneal treatment is performed for tuning the second metal layer 172 in the second opening 162 after removing the second metal layer 172 in the first active region 110. Consequently, the second metal layer 172 of multi-layered structure is more preferable for serving as the work function metal for n-type transistor. In other variance, the second metal layer 172 is first blanketly formed on the substrate 100 and followed by performing an ion implantation. Accordingly, the second metal layer 172 in the first active region 110 is converted to the first metal layer 170 for serving as the work function metal for p-type transistor. Those skilled in the art would easily realize the aforementioned methods for forming the first metal layer 170 and the second metal layer 172 are exemplarily disclosed and can be used according to the requirement to the product or process, but not limited to this. Therefore those details are omitted herein in the interest of brevity. Additionally, a high-K last process, that is to form the high-K gate dielectric layer after the recess elimination step 158, can be selectively integrated into the provided method and followed by forming the gate metal layers as mentioned above.

Please refer to FIG. 4. Then, a planarization process preferably a CMP process is performed to remove unnecessary filling metal layer 174, first metal layer 170, and second metal layer 172. It is noteworthy that because the CMP process is more preferable for removing protrusion than for removing indentation from a surface, the spacer protrusion 136 protruded from the ILD layer 152 are all eliminated in the CMP process. Accordingly, a first metal gate 180 of the first conductive-type transistor 120 and a second metal gate 182 of the second conductive-type transistor 122 are obtained after the CMP process. Furthermore, top surfaces of the first metal gate 180 and the second metal gate 182, the ILD layer 152 and the CESL 150 are all co-planar after the CMP process as shown in FIG. 4.

According to the first preferred embodiment of the present invention, after simultaneously removing the dummy gates of the first conductive-type transistor 120 and the second conductive-type transistor 122 and forming the recesses 154, the DHF etching process 158 is performed to remove a portion of the ILD layer 152, such that the ILD layer 152 and the bottom of the recess 154 are co-planar. In other words, the DHF etching process 158 eliminates the recesses 154 and forms the spacer protrusion 136 on the ILD layer 152. Therefore, the CMP process that is more preferable for removing the protrusion is used to remove the spacer protrusion 136 in one-time. Consequently, no metal remnant except the first metal gate 180 and the second metal gate 182 is left on the substrate 100.

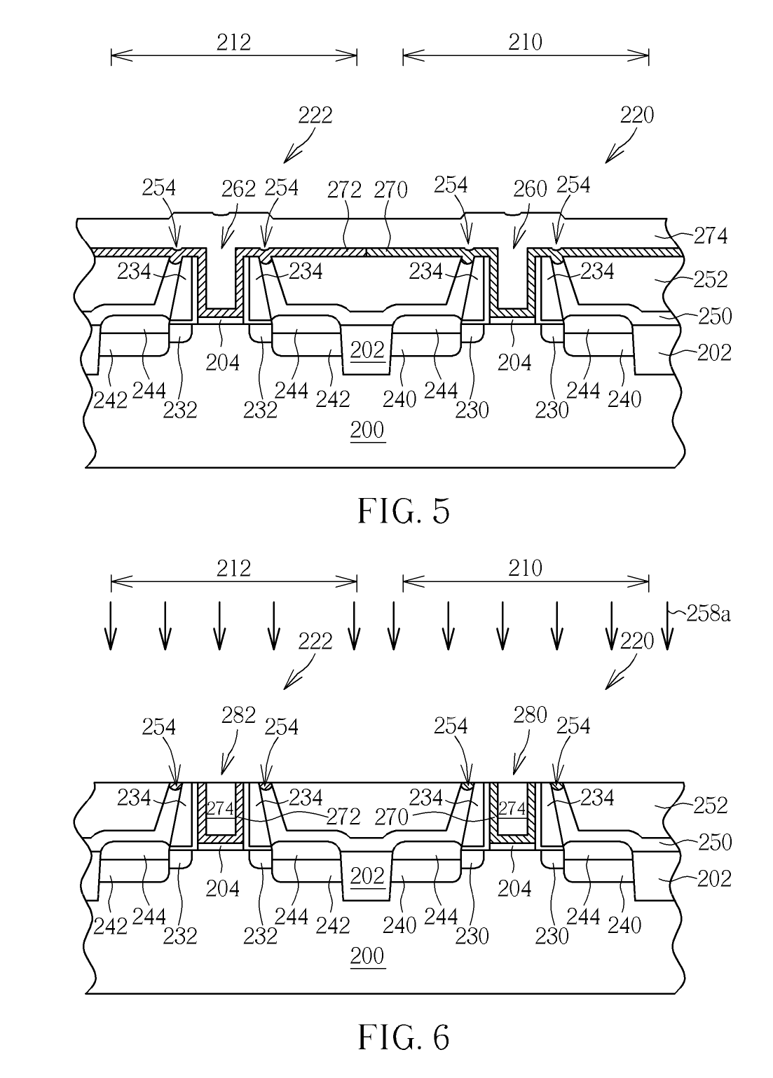

Please refer to FIGS. 5-7, which are schematic drawings illustrating a method of manufacturing a semiconductor device having metal gate provided by a second preferred embodiment of the present invention. It is noteworthy that in the second preferred embodiment, materials for forming elements are the same with the first preferred embodiment, and therefore are omitted for the sake of simplicity. As shown in FIG. 5, the preferred embodiment first provides a substrate 200 having a first active region 210 and a second active region 212 defined thereon. The substrate 200 also includes a plurality of STIs 202 for electrically isolating the first active region 210 and the second active region 212. Then, a first conductive-type transistor 220 and a second conductive-type transistor 222 are formed on the substrate 200 respectively in the first active region 210 and the second active region 212. In the preferred embodiment, the first conductive-type transistor 220 is a p-type transistor and the second conductive-type transistor 222 is an n-type transistor, or vice versa. Accordingly, the semiconductor device provided by the preferred embodiment is a CMOS device.

As shown in FIG. 5, the first conductive-type transistor 220 and the second conductive-type transistor 222 respectively include a gate dielectric layer 204, a dummy gate (not shown), and a patterned hard mask (not shown). The first conductive-type transistor 220 and the second conductive-type transistor 222 further respectively includes a first LDD 230 and a second LDD 232, a spacer 234, and a first source/drain 240 and a second source/drain 242. As mentioned above, a SEG method can be introduced to form the first source/drain 240 and the second source/drain 242 in the preferred embodiment. Thereafter, salicides 244 are formed on the first source/drain 240 and the second source/drain 242. After forming the first conductive-type transistor 220 and the second conductive-type transistor 222, a CESL 250 and an ILD layer 252 covering the first conductive-type transistor 220 and the second conductive-type transistor 222 are sequentially formed on the substrate 200.

Please refer to FIG. 5 again. Then, a conventional planarization process such as a CMP process is performed to planarize the ILD layer 252 and the CESL 250 to expose the dummy gates. After the planarization process, a dummy gate removal step 256 is performed to simultaneously remove the dummy gates of the first conductive-type transistor 220 and the second conductive-type transistor 222 and to form a first opening 260 and a second opening 262 respectively in the first conductive-type transistor 220 and the second conductive-type transistor 222. Additionally, the gate dielectric layer 204 is exposed in bottoms of the first opening 260 and the second opening 262. It is noteworthy the dummy gate removal step 256 simultaneously removes a portion of the CESL 250. Consequently, a top surface of the CESL 250 is lower than the spacers 234 of the first conductive-type transistor 220 and the second conductive-type transistor 222 and the ILD layer 252. Therefore, a plurality of recesses 254 is obtained, and the recess 254 has a depth in a range of 50-150 Å.

Please still refer to FIG. 5. Next, a barrier layer (not shown) is respectively formed in the first opening 260 and the second opening 262. After forming the barrier layer, a first metal layer 270 and a second metal layer 272 are respectively formed in the first opening 260 and the second opening 262. The first metal layer 270 includes a work function metal for p-type transistor and the second metal layer 272 includes a work function metal for n-type transistor. Then, a filling metal layer 274 is formed to fill the first opening 260 and the second opening 262 on the substrate 200. It is noteworthy the first metal layer 270, the second metal layer 272 and the filling metal layer 274 fill the recesses 254 as shown in FIG. 5. As mentioned above, the first metal layer 270 and the second metal layer 272 can be single-layered or multi-layered structures formed by different methods. Those methods are described in the first preferred embodiment; therefore the details are omitted herein. In addition, high-K last process can be integrated into the method provided by the preferred embodiment.

Please refer to FIG. 6. After forming the first metal layer 270, the second metal layer 272 and the filling metal layer 274, a recess elimination step is performed. According to the preferred embodiment, the recess elimination step is a two-stepped method: a metal-chemical mechanical polish (metal-CMP) step 258a is first performed to remove unnecessary filling metal layer 274, first metal layer 270 and second metal layer 272. It is noteworthy that the metal-CMP step 258a is stopped at a surface of the ILD layer 252. Consequently, a first metal gate 280 of the first conductive-type transistor 220 and a second metal gate 282 of the second conductive-type transistor 222 that are co-planar with the ILD layer 252 are obtained.

Accordingly, the preferred embodiment further provides a semiconductor device having metal gate. The semiconductor device includes the substrate 200, the metal gate 280/282 positioned on the substrate 200, the spacer 234 formed on a sidewalls of the metal gate 280/282, and the CESL 250 and the ILD layer 252 covering the spacer 234. It is noteworthy that the top surface of the CESL 250 is lower than the spacer 234 and the ILD layer 252 and thus the recesses 254 are formed. The recesses 254 are filled with the metal layers 270, 272 or 274. As mentioned above, the metal gate 280/282 includes the gate dielectric layer 204 positioned on the substrate 200, the work function metal layer 270 or 272 positioned on the gate dielectric layer 204, and the filling metal layer 274 positioned on the work function metal layer 270 or 272. The first metal layer 272 of the first metal gate 280 includes metal materials for p-type transistor and serves as its work function metal, and the second metal gate 282 of the second metal gate 282 includes metal materials for n-type transistor and serves as its work function metal. And the recess 254 has the depth of 50-150 Å.

Please refer to FIG. 7. The second step of the recess elimination step, a non-selectivity CMP step 258b, is then performed. Different from the metal-CMP step 258a, the non-selectivity CMP step 258b is a CMP method without any selectivity. Therefore, the non-selectivity CMP step 258b is performed to remove the ILD layer 252 and the metal layers 270/272/274 in the recesses 254. Accordingly, the non-selectivity CMP step 258b completely removes recesses 254 and the metal layers 270/272/274 formed within. As shown in FIG. 7, the ILD layer 252, the CESL 250, the spacer 234, the first metal layer 270, the second metal layer 272, and the filling metal layer 274 are all co-planar after the non-selectivity CMP step 258b. In other words, abovementioned layers are all co-planar with the bottom of the previously existed recesses 254.

According to the second preferred embodiment of the present invention, after forming the first metal layer 270, the second metal layer 272, and the filling metal layer 274, the recess elimination step is performed to remove the recesses 254 and the metal layers formed within: the first step is to perform the metal-CMP step 258a to remove the unnecessary filling metal layer 274, first metal layer 270, and second metal layer 272. The second step is to subsequently perform the non-selectivity CMP step 258b to remove the ILD layer 252 and the metals layer 270/272/274 in the recesses 254. By performing the two-stepped recess elimination step, the recesses 254 and the metal layers formed within are completely removed. Consequently, no metal remnant except the first metal gate 280 and the second metal gate 282 is left on the substrate 200.

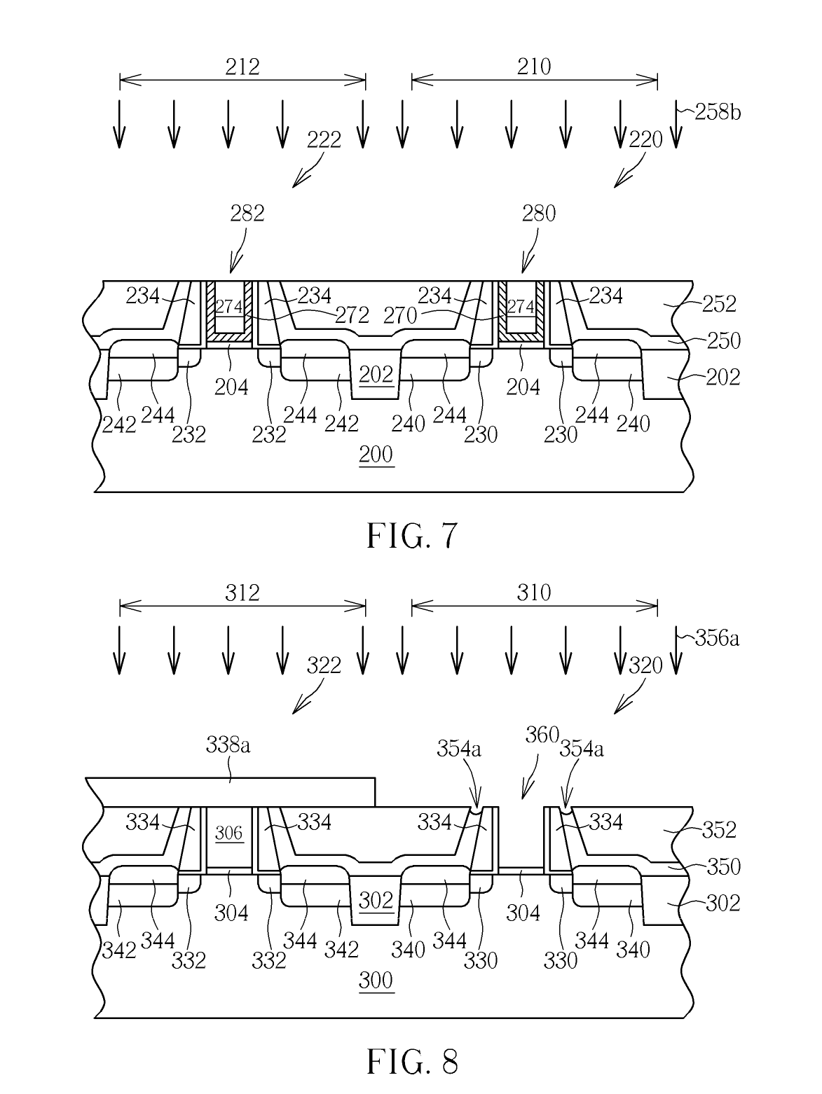

Please refer to FIGS. 8-12, which are schematic drawings illustrating a method of manufacturing a semiconductor device having metal gate provided by a third preferred embodiment of the present invention. It is noteworthy that in the third preferred embodiment, materials for forming elements are the same with the aforementioned preferred embodiment, and therefore are omitted for the sake of simplicity. As shown in FIG. 8, the preferred embodiment provides a substrate 300 having a first active region 310 and a second active region 312 defined thereon. And a plurality of STIs 302 is formed in substrate 300 for electrically isolating the first active region 310 and the second active region 312. Next, a first conductive-type transistor 320 and a second conductive-type transistor 322 are formed on the substrate 300 respectively in the first active region 310 and the second active region 312. In the preferred embodiment, the first conductive-type transistor 320 is a p-type transistor and the second conductive-type transistor 322 is an n-type transistor, or vice versa.

As shown in FIG. 8, the first conductive-type transistor 320 and the second conductive-type transistor 322 respectively include a gate dielectric layer 304, a dummy gate 306 such as a polysilicon layer and a patterned hard mask (not shown). The first conductive-type transistor 320 and the second conductive-type transistor 322 further respectively includes a first LDD 330 and a second LDD 332, a spacer 334, and a first source/drain 340 and a second source/drain 342. As mentioned above, a SEG method can be introduced to form the first source/drain 340 and the second source/drain 342 in the preferred embodiment. Thereafter, salicides 344 are formed on the first source/drain 340 and the second source/drain 342. After forming the first conductive-type transistor 320 and the second conductive-type transistor 322, a CESL 350 and an ILD layer 352 are sequentially formed to cover the first conductive-type transistor 320 and the second conductive-type transistor 322 on the substrate 300.

Please still refer to FIG. 8. Then, a conventional planarization process such as a CMP process is performed to planarize the ILD layer 352 and the CESL 350 and to expose the dummy gates 306 of the first conductive-type transistor 320 and the second conductive-type transistor 322. Next, a patterned hard mask 338a is formed in the second active region 312 for protecting the dummy gate 306 in the second active region 312. After forming the patterned hard mask 338, a first dummy gate removal step 356a is performed to remove the dummy gate 306 of the first conductive-type transistor 320 and form a first opening 360 in the first conductive-type transistor 320. And the gate dielectric layer 304 is exposed in a bottom of the first opening 360. Simultaneously, the first dummy gate removal step 356a removes a portion of the CESL 350. Consequently, a top surface of the CESL 350 is lower than the spacer 334 of the first conductive-type transistor 320 and the ILD layer 352, and thus a plurality of recesses 354a having a depth in range of 50-150 Å is obtained.

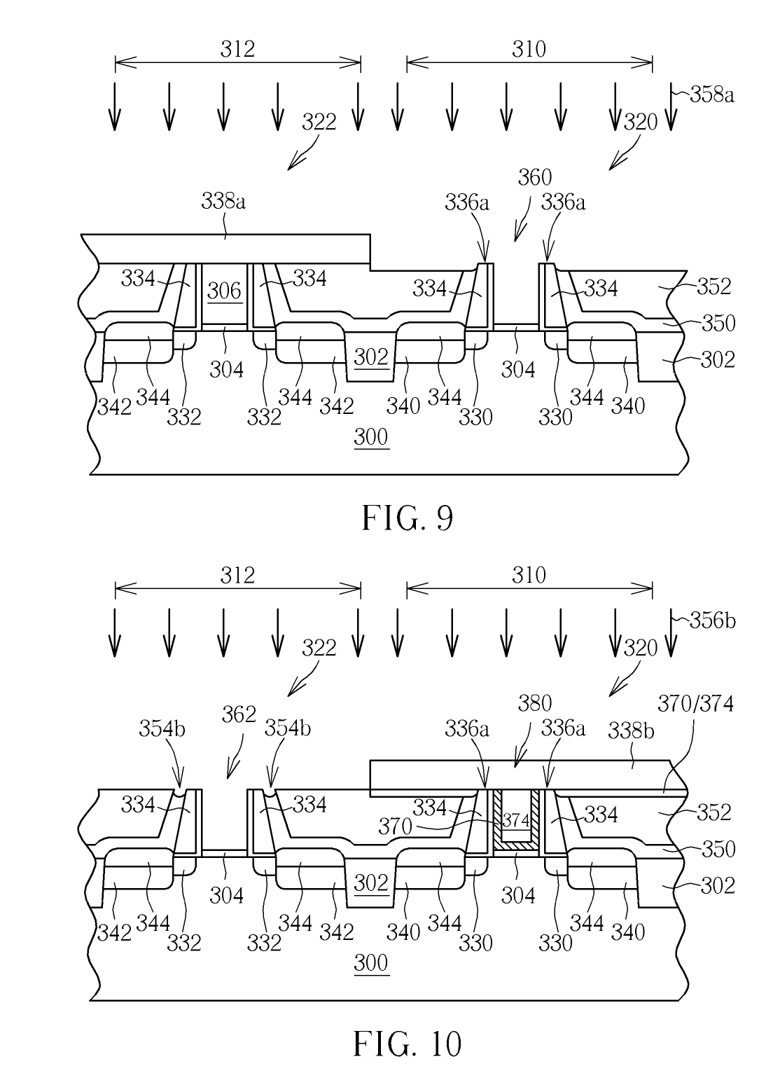

Please refer to FIG. 9. Next, a first etching process preferably a DHF etching process 358a, such as a wet etching or dry etching process comprising the DHF, is performed. The first etching process is performed to remove a portion of the ILD layer 352 and thus a top surface of the ILD layer and a bottom of the recesses 354a are co-planar. Accordingly, the recesses 354a are eliminated and a substantially even surface of the ILD layer 352 from which a spacer protrusion 336a is protruded is obtained as shown in FIG. 9.

Please refer to FIG. 10. After eliminating the recesses 354a and forming the spacer protrusion 336a, the patterned hard mask 338a is removed and followed by sequentially forming a barrier layer (not shown), a first metal layer 370 and a filling metal layer 374 in the first opening 360 with the filling metal layer 374 filling the first opening 360. As mentioned above, the first metal layer 370 includes a work function metal for p-type transistor and the filling metal layer 374 includes metal having superior gap-fill ability. Additionally, a high-K dielectric layer (not shown) can be selectively formed after the first etching process. After forming the first metal layer 370 and the filling metal layer 374, a first planarization process, such as a CMP process is performed to remove a portion of filling metal layer 374 and the first metal layer 370. Thus, a first metal gate 380 of the first conductive-type transistor 320 is obtained.

Please refer to FIG. 10 again. After forming the first metal gate 380, another patterned hard mask 338b is formed in the first active region 310 for protecting the first metal gate 380 in the first active region 312. Then, a second dummy gate removal step 356b is performed to remove the dummy gate 306 of the second conductive-type transistor 322 to form a second opening 362 in the second conductive-type transistor 322. And the gate the dielectric layer 304 is exposed in a bottom of the second opening 362. Simultaneously, the second dummy gate removal step 356b removes a portion of the CESL 350 and thus a top surface of the CESL 350 is lower than the spacer 334 of the second conductive-type transistor 322 and the ILD layer 352. Accordingly, a plurality of recesses 354b is obtained, and a depth of the recess 354b is the same with that of the recess 354a.

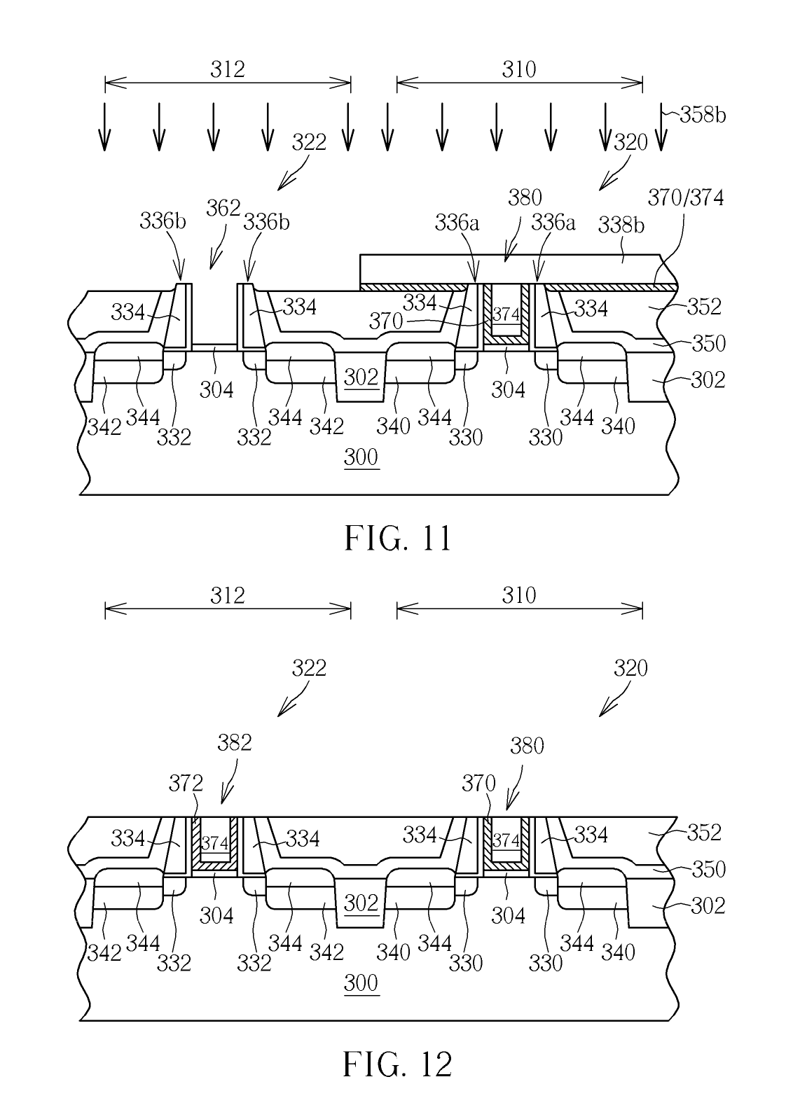

Please refer to FIG. 11. Then, a second etching process preferably a DHF etching process 358b such as wet etching or dry etching process comprising the DHF is performed to remove a portion of the ILD layer 352. Accordingly, a top surface of the ILD layer 352 and a bottom of the recesses 354b are co-planar. After the second etching process, the recesses 354b are eliminated and a substantially even surface of the ILD layer 352 from which a spacer protrusion 356a is protruded is obtained as shown in FIG. 11.

Please refer to FIG. 12. After removing the recesses 354b and forming the spacer protrusion 336b, a barrier layer (not shown) is formed and followed by sequentially forming a second metal layer 372 and the filling metal layer 374 in the second opening 362. The filling metal layer fills the second opening 362. As mentioned above, the second metal layer 372 includes a work function metal for n-type transistor and the filling metal layer 374 includes metal having superior gap-fill ability. Additionally, a high-K dielectric layer (not shown) can be formed after the second etching process. After forming the second metal layer 372 and the filling metal layer 374, a second planarization process, such as a CMP process is performed to remove a portion of the filling metal layer 374 and the second metal layer 372. Thus, a second metal gate 382 of the second conductive-type transistor 322 is obtained. It is noteworthy that because the CMP process is more preferable for removing protrusion than for removing indentation from a surface, the spacer protrusion 336a/336b protruded from the ILD layer 352 are all eliminated in the CMP process simultaneously with removing the unnecessary metal layer on the ILD layer 352. Accordingly, a top surface of the first metal gate 380 and the second metal gate 382, the ILD layer 352 and the CESL 350 are all co-planar after the CMP process as shown in FIG. 12.

Furthermore, in a modification to the preferred embodiment, the CMP process can be a two-stepped process: a metal-CMP step (not shown) is first performed to remove the unnecessary filling layer 374, first metal layer 370 and second metal layer 372. Then, a non-selectivity CMP step (not shown) is performed to remove the ILD layer 352, the recesses 354a/354b, and the metal layers 370/372/374 in the recesses 354a/354b. Accordingly, the recesses 354a/354b and the metal layers within are all eliminated.

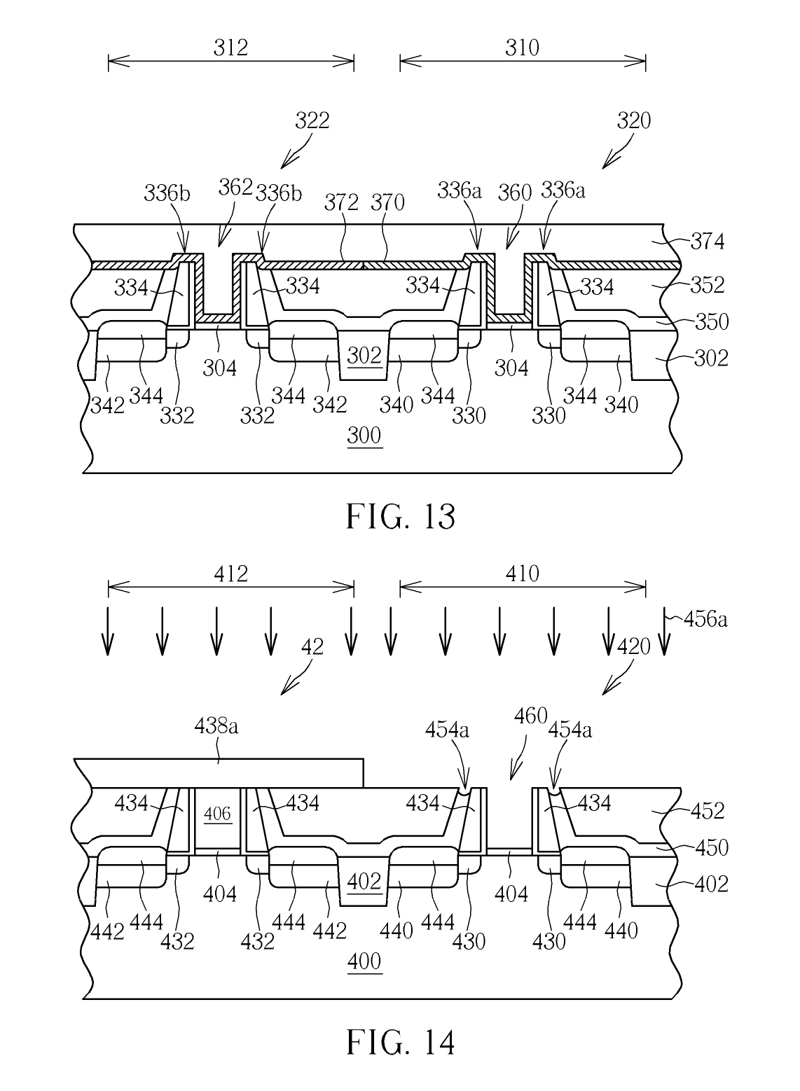

Please refer to FIG. 13, which is a schematic drawing illustrating a modification to the third preferred embodiment. The main difference between the modification and the third preferred embodiment is: the filling metal layer 374 filling the first opening 360 and the second opening 362 is simultaneously formed. For example, after forming the first metal layer 370 in the first opening 360, the patterned hard mask (not shown) is subsequently formed in the first active region 310 for protecting the first metal layer 370 in the first active region 310. Then, the dummy gate 306 of the second conductive-type transistor 322 is removed and followed by removing the patterned hard mask in the first active region 310. Thereafter, the second metal layer 372 and the filling metal layer 374 are sequentially formed on the substrate 300 with the filling metal layer 374 filling the first opening 360 and the second opening 362. After forming all of the required metal layers, the CMPS process is performed to remove the unnecessary metals in one-time or in two-steps as mentioned above. As mentioned above, since the CMP process is more preferable for removing protrusion from a surface, the spacer protrusion 336a/336b protruded from the ILD layer 352 are all eliminated in the CMP process simultaneously with removing the unnecessary metal layers on the ILD layer 352.

According to the third preferred embodiment of the present invention, after respectively removing the dummy gates 306 of the first conductive-type transistor 320 and the second conductive-type transistor 322 to form the recesses 354a/354b, the DHF etching processes 358a/358b are respectively performed to remove a portion of the corresponding ILD layer 352, therefore the ILD layer 352 and the bottom of the recess 354a/354b are co-planar. In other words, the DHF etching processes 358a/358b eliminate the recesses 354a/354b and form the spacer protrusion 336a/336b on the ILD layer 352. Therefore, the CMP process that is more preferable for removing the protrusion is used to remove the spacer protrusion 336a/336b. Consequently, no metal remnant except the first metal gate 380 and the second metal gate 382 is left on the substrate 300.

Please refer to FIGS. 14-17, which are schematic drawings illustrating a method of manufacturing a semiconductor device having metal gate provided by a fourth preferred embodiment of the present invention. It is noteworthy that in the fourth preferred embodiment, materials for forming elements are the same with the aforementioned preferred embodiment, and therefore are omitted for the sake of simplicity. As shown in FIG. 14, the preferred embodiment provides a substrate 400 having a first active region 410 and a second active region 412 defined thereon. And a plurality of STIs 402 is formed in the substrate 400 for electrically isolating the first active region 410 and the second active region 412. Next, a first conductive-type transistor 420 and a second conductive-type transistor 422 are formed on the substrate 400 respectively in the first active region 410 and the second active region 412. In the preferred embodiment, the first conductive-type transistor 420 is a P-type transistor and the second conductive-type transistor 422 is an N-type transistor, or vice versa.

As shown in FIG. 14, the first conductive-type transistor 420 and the second conductive-type transistor 422 respectively include a gate dielectric layer 404, a dummy gate 406 such as a polysilicon layer and a patterned hard mask (not shown). The first conductive-type transistor 420 and the second conductive-type transistor 422 further respectively include a first LDD 430 and a second LDD 432, a spacer 434, and a first source/drain 440 and a second source/drain 442. As mentioned above, a SEG method can be introduced to form the first source/drain 440 and the second source/drain 442 in the preferred embodiment. Thereafter, salicides 444 are formed on the first source/drain 440 and the second source/drain 442. After forming the first conductive-type transistor 420 and the second conductive-type transistor 422, a CESL 450 and an ILD layer 452 are sequentially formed to cover the first conductive-type transistor 420 and the second conductive-type transistor 422 on the substrate 400.

Please still refer to FIG. 14. Next, a conventional planarization process such as CMP process is performed to planarize the ILD layer 452 and the CESL 450 and followed by forming a patterned hard mask 438a in the second active region 412 for protecting the dummy gate 406 in the second active region 412. After forming the patterned hard mask 438a, a first dummy gate removal step 456a is performed to remove the dummy gate 406 of the first conductive-type transistor 420 to form a first opening 460 in the first conductive-type transistor 420. And the gate dielectric layer 404 is exposed in a bottom of the first opening 460. Simultaneously, the first dummy gate removal step 456a also removes a portion of the CESL 450 and therefore a top surface of the CESL 450 is lower than the spacer 434 of the first conductive-type transistor 420 and the ILD layer 452. Accordingly, a plurality of recesses 454a is formed and the recess 454a has a depth in a range of 50-150 Å.

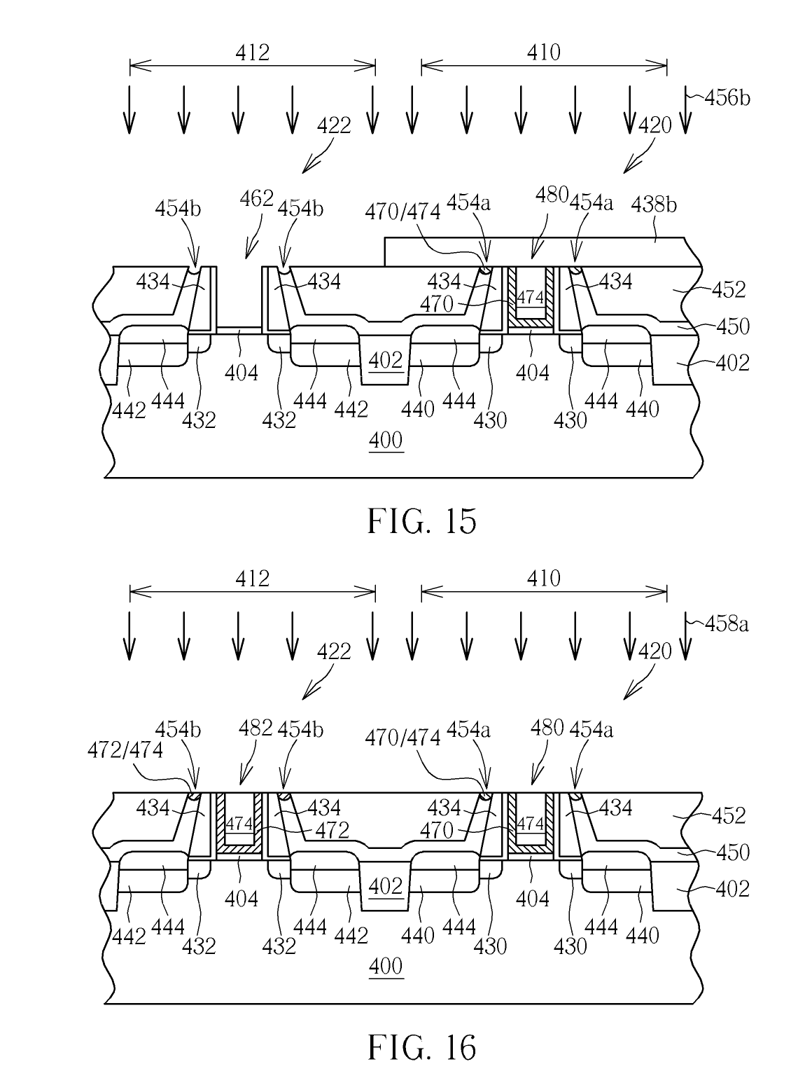

Please refer to FIG. 15. After removing the patterned hard mask 438a, a barrier layer (not shown), a first metal layer 470 and a filling metal layer 474 are sequentially formed in the first opening 460, with the filling metal layer 474 filling the first opening 460. As mentioned above, the first metal layer 470 includes a work function metal for p-type transistor and the filling metal layer 474 includes metal having superior gap-fill ability. Additionally, a high-K dielectric layer (not shown) can be formed after removing the dummy gate 406. Thereafter, a first planarization process preferably a metal-CMP process is performing to remove a portion of the filling metal layer 474 and the first metal layer 470. Consequently, a first metal gate 480 of the first conductive-type transistor 420 is obtained. It is noteworthy that the metal-CMP step is stopped at a surface of the ILD layer 452 and accordingly a portion of the first metal layer 470 and the filling metal layer 474 are still remained in the recesses 454a as shown in FIG. 15.

Please still refer to FIG. 15. After forming the first metal gate 480, a patterned hard mask 438b is formed in the first active region 410 for protecting the first metal gate 480 in the first active region 412. Then, a second dummy gate removal step 456b is performed to remove the dummy gate 406 of the second conductive-type transistor 422 to form a second opening 462 in which the gate dielectric layer 404 is exposed. Simultaneously, the second dummy gate removal step 456b removes a portion of the CELS 450, and therefore a top surface of the CESL 450 is lower than the spacer 434 of the second conductive-type transistor 422 and the ILD layer 452. Consequently, a plurality of recesses 454b is formed, and a depth of the recess 454b is the same with that of the recess 454a.

Please refer to FIG. 16. Next, the patterned hard mask 438b is removed and followed by forming a barrier layer (not shown), a second metal layer 472 and the filling metal layer 474 in the second opening 462. The filling metal layer 474 fills the second opening 462. Additionally, a high-K dielectric layer (not shown) can be formed before forming the barrier layer. As mentioned above, the first metal layer 472 includes a work function metal for n-type transistor and the filling metal layer 474 includes the metal having superior gap-fill ability. After forming the second metal layer 472 and the filling metal layer 474, a metal-CMP process 458a is performed to remove the unnecessary filling metal layer 474 and second metal layer 472. It is noteworthy that the metal-CMP process 458a is stopped at the surface of the ILD layer. Consequently, a second metal gate 482 of the second conductive-type transistor 422 is obtained.

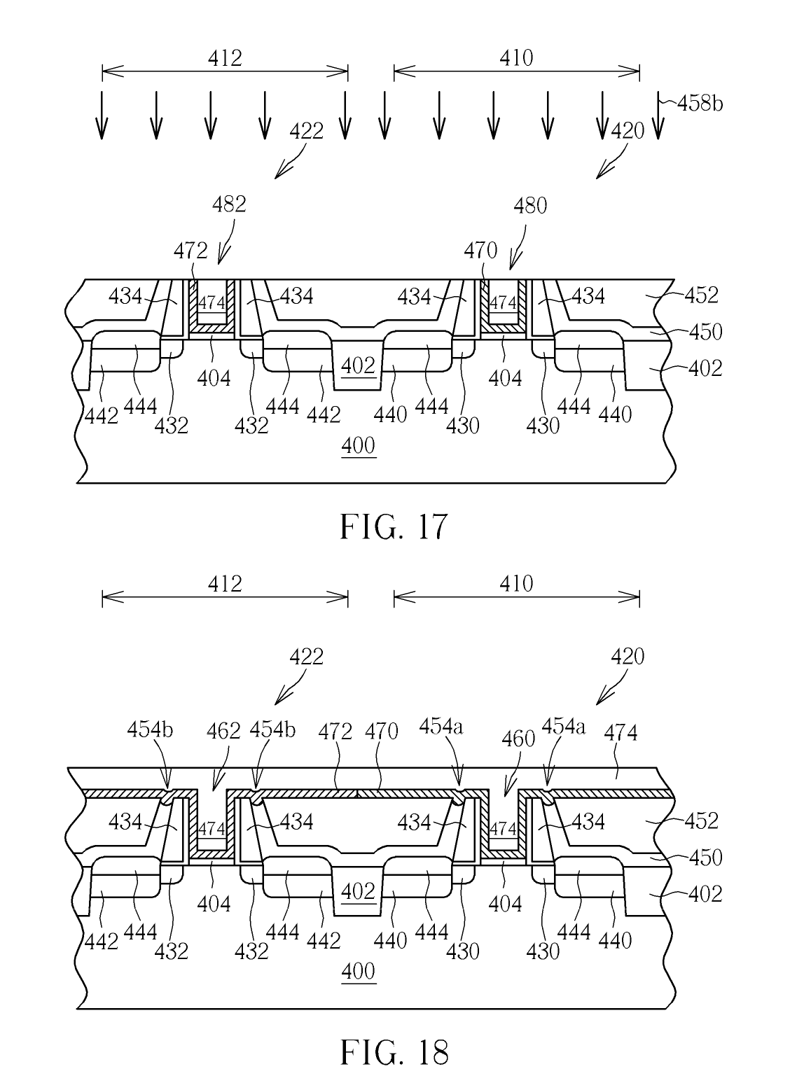

Please refer to FIG. 17. Next, a non-selectivity CMP process 458b is performed. Different from the metal-CMP process 458a, the non-selectivity CMP step 458b is a CMP method without any selectivity. Therefore, the non-selectivity CMP step 458b is performed to remove the ILD layer 452 and the metal layers 470/472/474 in the recesses 454a/454b. Accordingly, the non-selectivity CMP step 258b completely removes the recesses 454a/454b and the metal layers 470/472/474 within. As shown in FIG. 17, the ILD layer 452, the CESL 450, the spacers 434, the first metal layer 470, the second metal layer 472, and the filling metal layer 474 are all co-planar after the non-selectivity CMP step 458b, that is co-planar with the bottom of the recesses 454a/454b.

Please refer to FIG. 18, which is a schematic drawing illustrating a modification to the fourth preferred embodiment. The main difference between the modification and the fourth preferred embodiment is: the filling metal layer 474 filling the first opening 460 and the second opening 462 is simultaneously formed. For example, after forming the first metal layer 470 in the first opening 460, the patterned hard mask (not shown) is subsequently formed in the first active region 410 for protecting the first metal layer 470 in the first active region 410. Then, the dummy gate 406 of the second conductive-type transistor 422 is removed and followed by removing the patterned hard mask in the first active region 410. Thereafter, the second metal layer 472 and the filling metal layer 474 are sequentially formed on the substrate 400 with the filling metal layer 474 filling the first opening 460 and the second opening 462. After forming all of the required metal layers, the metal-CMP process 458a is first performed to remove the unnecessary third metal layer 474, second metal layer 472 and first metal layer 470 as shown in FIG. 16. As mentioned above, the first metal layer 470 and the third metal layer 474 are remained in the recesses 454a while the second metal layer 472 and the third metal layer 474 are remained in the recesses 454b after the metal-CMP process. Then, the non-selectivity CMP process 458b is performed to remove the ILD layer 452 and the metal layers 470/472/474 in the recesses 454a/454b. Accordingly, the recesses 454a/454b and the metal layers 470/472/474 within are eliminated after the non-selectivity CMP process 458b. It is noteworthy that the ILD layer 452, the CESL 450, the spacers 434, the first metal layer 470, the second metal layer 472, and the filling metal layer 474 are all co-planar. That is, to be co-planar with the bottom of the recesses 454a/454b.

Furthermore, it is not limited to perform a DHF etching process to remove a portion the ILD layer 452 after forming the first opening 460 and the recesses 454a. Accordingly, the top surface of the ILD layer 452 is co-planar with the bottom of the recesses 454a. In the same concept, it is not limited to perform another DHF etching process to remove a portion of the ILD layer 452 after forming the second opening 462 and the recesses 454b. Accordingly, the top surface of the ILD layer 452 is co-planar with the bottom of the recesses 450b. Then, after forming the first metal layer 470, the second metal layer 472 and the third metal layer 474, the two-stepped CMP process comprising the metal-CMP step 458a and the non-selectivity CMP step 458b is performed.

According to the fourth preferred embodiment of the present invention, after respectively forming the first opening 460 and the second opening 462, and after respectively forming the first metal layer 470, the second metal layer 472, and the filling metal layer 474, the metal-CMP step 458a is performed to remove the unnecessary filling metal layer 474, first metal layer 470, and second metal layer 472. Then the non-selectivity CMP step 458b is performed to remove the ILD layer 452 and the metals layer 470/472/474 in the recesses 454a/454b. By performing the two-stepped CMP process, the recesses 454a/454b and the metal layers 470/472/474 formed within are completely removed. Consequently, no metal remnant except the first metal gate 480 and the second metal gate 482 is left on the substrate 400.

According to the semiconductor device having metal gate and manufacturing method provided by present invention, the recesses formed in the CESL are eliminated by performing the recess elimination step such as the etching process performed before forming the metal layers or the two-stepped planarization process performed after forming the metal layers. Consequently, the recesses and the metal layers filled within are all removed and thus the electrical performance of the semiconductor device will not be adversely impacted.

Those skilled in the art will readily observe that numerous modifications and alterations of the device and method may be made while retaining the teachings of the invention.

What is claimed is:

1. A method of manufacturing a semiconductor device having metal gate, comprising:
providing a substrate having at least a semiconductor device and a contact etch stop layer (CESL) and a dielectric layer covering the semiconductor device formed thereon, the semiconductor device having at least a dummy gate;
performing a dummy gate removal step to form at least an opening in the semiconductor device, and to simultaneously remove a portion of the CESL such that a top surface of the CESL is lower than the semiconductor device and the dielectric layer and a plurality of recesses is obtained; and
performing a recess elimination step to form a substantially even surface of the dielectric layer.

2. The method of manufacturing a semiconductor device having metal gate according to claim 1, wherein the recess elimination step comprises a dilute HF (DHF) etching process performed to etch the dielectric layer.

3. The method of manufacturing a semiconductor device having metal gate according to claim 2, wherein the top surface of the dielectric layer and a bottom of the recesses are co-planar after the recess elimination step.

4. The method of manufacturing a semiconductor device having metal gate according to claim 2, further comprising steps of forming at least a metal layer on the substrate and performing a planarization process after the recess elimination step.

5. The method of manufacturing a semiconductor device having metal gate according to claim 1, further comprising a step of forming at least a metal layer on the substrate before performing the recess elimination step.

6. The method of manufacturing a semiconductor device having metal gate according to claim 5, wherein the recess elimination step further comprises:
performing a metal-chemical mechanical polish (metal-CMP) step; and
performing a non-selectivity CMP step.

7. The method of manufacturing a semiconductor device having metal gate according to claim 6, wherein the metal layer, the dielectric layer, and the CESL are co-planar after the recess elimination step.

8. The method of manufacturing a semiconductor device having metal gate according to claim 1, wherein the semiconductor device comprises a complementary metal-oxide semiconductor (CMOS) device, the CMOS device further comprises a first conductive-type transistor and a second conductive-type transistor, and the first conductive-type transistor and the second conductive-type transistor respectively comprise the dummy gate.

9. The method of manufacturing a semiconductor device having metal gate according to claim 8, wherein the dummy gate removal step simultaneously removes the dummy gates of the first conductive-type transistor and second conductive-type transistor.

10. A method of manufacturing a semiconductor device having metal gate, comprising:
providing a substrate having a first transistor, a second transistor, and a contact etch stop layer (CESL) and a dielectric layer covering the first transistor and the second transistor formed thereon;
performing a first dummy gate removal step to form a first opening in the first transistor and simultaneously remove a portion of the CESL such that a top surface of the CESL is lower than the first transistor and the dielectric layer and a plurality of first recesses is obtained;
performing a first etching process to remove a portion of the dielectric layer such that a top surface of the dielectric layer and a bottom of the first recesses are co-planar;
forming a first metal layer in the first opening;
performing a second dummy gate removal step to form a second opening in the second transistor; and
forming a second metal layer in the second opening.

11. The method of manufacturing a semiconductor device having metal gate according to claim 10, wherein the second dummy gate removal step simultaneously removes a portion of the CESL such that a top surface of the CESL is lower than the second transistor and the dielectric layer and a plurality of second recesses is obtained.

12. The method of manufacturing a semiconductor device having metal gate according to claim 11, further comprising a step of performing a second etching process to remove a portion of the dielectric layer after forming the second opening, such that the top surface and a bottom of the second recesses are co-planar.

13. The method of manufacturing a semiconductor device having metal gate according to claim 10, further comprising a step of forming a third metal layer on the substrate.

14. The method of manufacturing a semiconductor device having metal gate according to claim 13, wherein the third metal layer is formed before removing the second dummy gate of the second transistor, and the third metal layer fills the first opening.

15. The method of manufacturing a semiconductor device having metal gate according to claim 14, further comprising a step of performing a planarization process to remove a portion of the third metal layer and the first metal layer.

16. The method of manufacturing a semiconductor device having metal gate according to claim 13, wherein the third metal layer is formed after forming the second metal layer and the third metal layer fills the first opening and the second opening.

17. The method of manufacturing a semiconductor device having metal gate according to claim 16, further comprising a step of performing a planarization process to remove a portion of the third metal layer, the first metal layer and the second metal layer, such that the first metal layer, the second metal layer, the third metal layer, the dielectric layer and the CESL are co-planar.

18. The method of manufacturing a semiconductor device having metal gate according to claim 17, wherein the planarization process further comprises:
performing a metal-CMP step; and
performing a non-selectivity CMP step.

19. A method of manufacturing a semiconductor device having metal gate, comprising:
providing a substrate having a first transistor, a second transistor, and a contact etching stop layer (CESL) and a dielectric layer covering the first transistor and the second transistor formed thereon;
performing a first dummy gate removal step to form a first opening in the first transistor and simultaneously remove a portion of the CESL;
forming a first metal layer in the first opening;
performing a second dummy gate removal step to form a second opening in the second transistor and simultaneously remove a portion of the CESL;
forming a second metal layer in the second opening;
forming a filling metal layer filling at least the second opening on the substrate;
performing a metal-CMP step to remove a portion of the filling metal layer; and
performing a non-selectivity CMP step such that the CESL, the dielectric layer and the filling metal layer are co-planar.

20. The method of manufacturing a semiconductor device having metal gate according to claim 19, wherein the first dummy gate removal step removes a portion of the CESL such that a top surface of the CESL is lower than the first transistor and the dielectric layer, and a plurality of first recesses is obtained.

21. The method of manufacturing a semiconductor device having metal gate according to claim 20, further comprising a step of performing a first etching process to remove a portion of the dielectric layer after forming the first opening and the first recesses, such that a top surface of the dielectric layer and a bottom of the first recesses are co-planar.

22. The method of manufacturing a semiconductor device having metal gate according to claim 19, further comprising a step of forming a third metal layer filling the first opening after forming the first metal layer.

23. The method of manufacturing a semiconductor device having metal gate according to claim 22, further comprising a step of performing a planarization process to remove a portion of the third metal layer after forming the third metal layer.

24. The method of manufacturing a semiconductor device having metal gate according to claim 19, wherein the second dummy gate removal step removes a portion of the CESL such that a top surface of the CESL is lower than the second transistor and the dielectric layer, and a plurality of second recesses is obtained.

25. The method of manufacturing a semiconductor device having metal gate according to claim 24, further comprising a step of performing a second etching process to remove a portion of the dielectric layer after forming the second opening and the second recesses, such that the top surface of the dielectric layer and a bottom of the second recesses are co-planar.

26. The method of manufacturing a semiconductor device having metal gate according to claim 19, wherein the non-selectivity CMP step removes the first recesses and the second recesses.

27. A semiconductor device having metal gate comprising:
a substrate;
a metal gate formed on the substrate;
a spacer formed on a sidewall of the metal gate;
a contact etch stop layer (CESL) and a dielectric layer covering the spacer, a top surface of the CESL being lower than the spacer and the dielectric layer and forming at least a recess; and
at least a metal layer filling the recess.

28. The semiconductor device according to claim 27, wherein the metal gate further comprises:
a gate dielectric layer positioned on the substrate;
a work function metal layer positioned on the gate dielectric layer; and
a filling metal layer positioned on the work function metal layer.

29. The semiconductor device according to claim 28, wherein the metal layer comprises at least the work function metal layer or the filling metal layer.

30. The semiconductor device according to claim 27, wherein the recess comprises a depth in a range of 50-150 angstroms.
